(19) United States
(12) Patent Application Publication
(10) Pub. No.: US 2017/0148812 A1
(43) Pub. Date: May 25, 2017

(54) METHODS AND APPARATUS FOR A 3D ARRAY INSIDE A SUBSTRATE TRENCH

(71) Applicant: Fu-Chang Hsu, San Jose, CA (US)

(72) Inventor: Fu-Chang Hsu, San Jose, CA (US)

(21) Appl. No.: 15/355,733

(22) Filed: Nov. 18, 2016

Related U.S. Application Data
(60) Provisional application No. 62/257,689, filed on Nov. 19, 2015.
(60) Provisional application No. 62/258,458, filed on Nov. 21, 2015.
(60) Provisional application No. 62/258,935, filed on Nov. 23, 2015.
(60) Provisional application No. 62/259,610, filed on Nov. 24, 2015.

(51) Int. Cl. H01L 27/115; H01L 21/768; H01L 21/306; H01L 23/528

(52) U.S. Cl. CPC H01L 27/11582; H01L 27/11568; H01L 27/11573; H01L 23/528; H01L 21/76877; H01L 21/30604

(57) ABSTRACT

A 3D array inside a substrate trench. In one aspect, an apparatus includes a substrate, a trench region in the substrate that is defined by a trench wall, and a 3D array having stacked word line layers formed in the trench region that follow a contour of the trench wall. In one aspect, a method includes forming a trench region in a substrate that has a top surface, the trench region is defined by a trench wall, and forming a 3D array having stacked word line layers in the trench region so that the stacked word line layers follow a contour of the trench wall and have exposed ends substantially at a level of the top surface.

This application claims the benefit of priority based upon U.S. Provisional Patent Application having Application No. 62/257,689,filed on Nov. 19, 2015,and entitled “3D ARRAY IN TRENCH REGION,” U.S. Provisional Patent Application having Application No. 62/258,458,filed on Nov. 21, 2015,and entitled “3D ARRAY INSIDE A TRENCH,” U.S. Provisional Patent Application having Application No. 62/258,935,filed on Nov. 23, 2015,and entitled “3D ARRAY INSIDE A TRENCH” and U.S. Provisional Patent Application having Application No. 62/259,610,filed on Nov. 24, 2015,and entitled “3D ARRAY INSIDE A TRENCH,” all of which are hereby incorporated herein by reference in their entireties.

### FIELD OF THE INVENTION

The exemplary embodiments of the present invention relate generally to the field of semiconductors and integrated circuits, and more specifically to memory and storage devices.

### BACKGROUND OF THE INVENTION

A conventional 3D array is manufactured on top of a substrate. By stacking multiple layers of cells, the 3D array has a significant height over the silicon surface of the substrate. For example, the typical height of 3D NAND flash array is about 3-5 um for 32-48 layers in today's 32-40 nm technology. The height of the 3D array results in a significant process challenge to connect the multiple layers vertically. Because the periphery circuits including decoders and logic are located on the surface of substrate, special back-end processes are required to connect the word lines (WL) and bit lines (BL) from each layer of the array to the top metal layer, and then to route down to the silicon surface to connect to decoders. This process requires a highly-precise deep-trench with a depth of 3-5 um and a large number of contact holes. Therefore, conventional 3D arrays pose significant process challenges, have reduced yields and increased manufacturing costs.

FIG. 1A shows a conventional 3D array chip 100 and FIG. 1B shows its cross-section view taken at cross section indicator 107. For example, FIG. 1A shows the 3D array 101, silicon substrate 102, word line decoder 105 and bit line decoder 106. The 3D array's word lines and bit lines need to be connected to the decoders 105 and 106 through contacts 103 and 104. Because of the height of the 3D array, it is very difficult to precisely pattern and deep-trench the contact holes to connect the word lines and bit lines of the array to the decoders. This represents a significant process challenge for 3D array manufacture.

Therefore, it is desirable to have a 3D array architecture and process that overcomes the problems associated with conventional 3D arrays.

### SUMMARY

Novel architectures and processes for forming 3D arrays inside a trench in a substrate are disclosed. In an exemplary embodiment, a 3D array is essentially buried inside the substrate, which reduces the overall height of the 3D array relative to the substrate surface and thus reduces process requirements. In an exemplary embodiment, if the depth of the trench is selected to be substantially equal to the height of the 3D array, the top of the 3D array is approximately at the level of the surface of the substrate silicon. Thus, the word lines and bit lines of the 3D array can be connected to the decoders and other periphery circuits mounted on the substrate surface by using standard back-end metal processes. The exemplary embodiments are suitable for use with any type of 3D array, such as a 3D NAND flash memory array, 3D anti-fuse array, 3D cross-point memory array, 3D PCM array, and many other 3D array types.

Compared with the conventional 3D array architecture, that is normally described as a “skyscraper”, exemplary embodiments of the novel 3D array architecture can be referred to as an “underground parking structure” or “multiple-floor basement.” In exemplary embodiments, the 3D array is formed inside a trench to make the silicon surface look ‘flat’, thus the traditional 2D process may be used to form the logic and back-end of the 3D array. Therefore, high-cost low-yield back-end processes of the conventional 3D array can be reduced or eliminated.

In an exemplary embodiment, an apparatus includes a substrate, a trench region in the substrate that is defined by a trench wall, and a 3D array having stacked word line layers formed in the trench region that follow a contour of the trench wall.

In an exemplary embodiment, a method is provided that comprises forming a trench region in a substrate that has a top surface, wherein the trench region is defined by a trench wall, and forming a 3D array having stacked word line layers in the trench region so that the stacked word line layers follow a contour of the trench wall and have exposed ends substantially at a level of the top surface.

In an exemplary embodiment, a 3D array is formed by performing the operations of forming a trench region in a substrate that has a top surface, wherein the trench region is defined by a trench wall, and forming a 3D array having stacked word line layers in the trench region so that the stacked word line layers follow a contour of the trench wall and have exposed ends substantially at a level of the top surface.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIGS. 1A-B show a conventional 3D array and its cross-sectional view;

FIGS. 2A-C show exemplary embodiments of a novel 3D process and architecture in which a 3D array is formed within a deep trench area in a silicon substrate;

FIG. 3 shows a cross-section view of a conventional 3D NAND array formed on top of a silicon substrate using a conventional process;

FIG. 4A shows an exemplary embodiment of a 3D NAND array constructed using an exemplary embodiment of the novel 3D array process and architecture;

FIG. 4B shows a cross-sectional view of the array shown in FIG. 4A taken along a bit line direction;

FIGS. 5A-H show exemplary embodiments of a simplified process flow for constructing a novel 3D array inside a substrate trench according to the invention;

FIG. 6 shows an exemplary embodiment of a 3D NAND flash array with ‘U’ shaped folded channels constructed in accordance with a novel 3D process and architecture of the present invention;

FIGS. 7A-B show exemplary embodiments of another implementation of the novel 3D process and architecture using a 3D NAND flash array having horizontal channels and a corresponding cross-sectional view;

FIGS. 7C-D show exemplary embodiments of another implementation of the novel 3D process and architecture in which only a 3D array's word line connection portion is located inside a trench and a corresponding cross-sectional view;

FIGS. 8A-F show exemplary embodiments of an implementation of the novel 3D architecture and process in which simplified process steps according to the invention are shown and described;

FIGS. 9A-D show exemplary embodiments of a process to prevent shorting of word line or bit line layers at the edge of a trench according to the invention;

FIGS. 10A-D show exemplary embodiments of additional examples for forming connections for multiple word line or bit line layers in accordance with the invention;

FIGS. 11A-C show various exemplary embodiments where a trench for a 3D array is formed using another suitable process, for example, by using epitaxial layers;

FIGS. 12A-B show additional exemplary embodiments for forming connections for multiple word line or bit line layers in accordance with the invention;

FIG. 12C shows another exemplary embodiment comprising stacked multiple layers of silicon substrates having 3D arrays formed in corresponding trenches in accordance with the invention;

FIG. 12D shows an exemplary embodiment of a stepped wall trench formed in a substrate in accordance with the invention; and

FIG. 13 shows an exemplary embodiment of method for performing process operations to implement a novel architecture to form a 3D array inside a trench of a substrate.

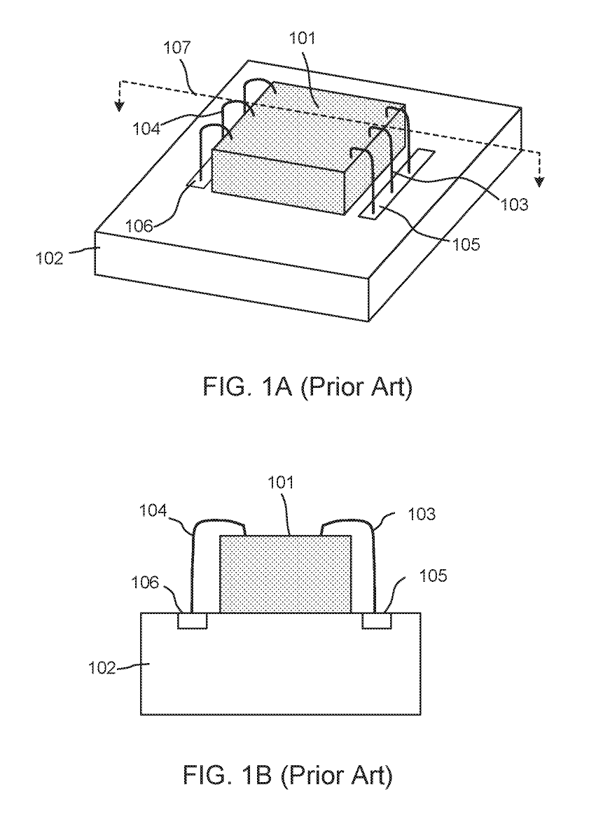

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

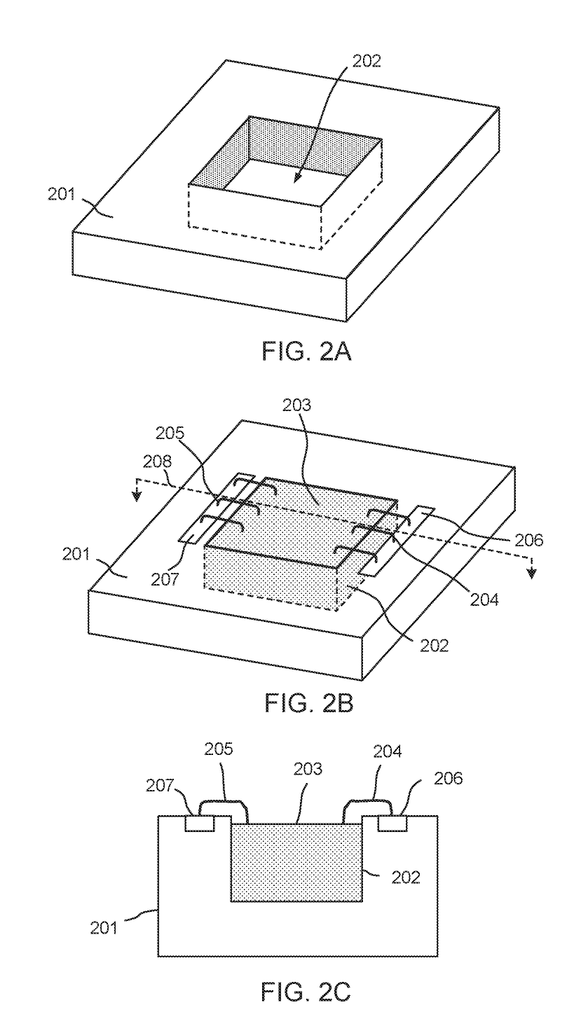

FIG. 2A shows an exemplary embodiment of a deep trench area 202 formed in a silicon substrate 201. For example, the trench area 202 can be etched in the substrate 201. The trench area 202 includes a bottom surface and side surfaces forming a three-dimensional space. In an exemplary embodiment, the bottom surface and side surfaces are considered as a continuous trench wall that defines or forms the trench area 202 or space. It should be noted that the trench area 202 is a rectangular area but the in other embodiments, the trench area can form any desired space or region, such as a square, triangle, cylinder or any other space or region.

FIG. 2B shows an exemplary embodiment of a 3D array 203 formed inside the trench area 202. FIG. 2C shows an exemplary embodiment of a cross-sectional view of the device shown in FIG. 2B taken at cross section indicator line 208. In an exemplary embodiment, the depth of the trench area 202 is selected according to the height of the 3D array 203. In an exemplary embodiment, the depth of the trench area 202 is selected to be close to or substantially the same as the height of the 3D array 203. Thus, after the 3D array is formed within the trench 202, the surface of the silicon substrate 201 remains substantially “flat.” As a result, word lines and bit lines of the array 203 can be connected to a word line decoder 206 and a bit line decoder 207 by using standard back-end metals 204 and 205. The novel architecture eliminates the traditional 3D array's deep contact etch and thus significantly reduces the process requirements and cost.

It should be noted that the various exemplary embodiments of the novel architecture can be implemented for any type of 3D array, such as 3D NAND flash array, 3D anti-fuse array, 3D cross-point memory array, 3D PCM array, and many others. Moreover, the novel architecture can be implemented in any process and technology, such as traditional silicon (bulk silicon), SOI (silicon on insulator), FinFET, and many others. For simplicity, in the following descriptions, a 3D NAND SONOS (silicon-oxide-nitride-oxide-silicon) flash memory will be used as an example. For example, the exemplary embodiments are described using 3D arrays having stacked word line layers. However, the embodiments are equally applicable to arrays having stacked bit line layers or a combination of bit line and word line layers. Thus, the use of word line layers in the below description is exemplary and does not limit the embodiments to implementations using only word line layers. Also, the application of the invention is not limited in any special products, technologies and processes. A person skilled in the art shall recognize that these variations shall remain within the scope of the invention.

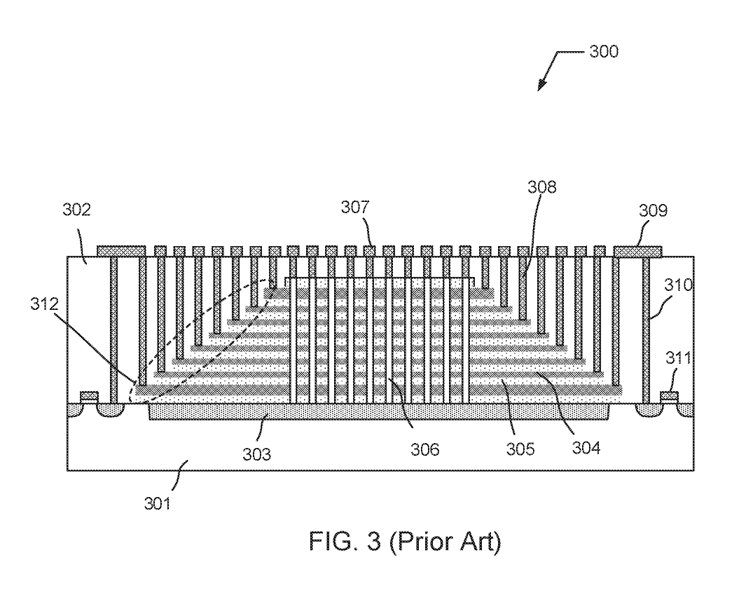

FIG. 3 shows a cross-section view of a conventional 3D NAND SONOS flash array 300 formed on top of a silicon substrate using a traditional approach. As shown in FIG. 3, the array 300 comprises a silicon substrate 301, a thick oxide layer 302, and a diffusion 303 for the array's source line (SL). Also shown are multiple layers of word lines 304 and insulator layers 305 between word line layers. Vertical channels 306 for the NAND string cells are formed by trenching holes (or openings) through all the word line layers (e.g., 304) and filling the channels 306 with polysilicon. Metal bit lines 307 are also shown.

During manufacture, to connect the multiple layers of word lines to the decoder 311 located on the silicon surface, a painstaking process is taken to etch the word line layers into a ‘staircase’ formation (shown at 312). This requires a special process called “photoresist pull-back” and pattern-etch for each layer. As a result, the process time and cost are significantly increased. After that, a special deep-trench process takes place to form the contact holes 308 that land on the staircase of each word line layer. The word lines are connected to the top metal 309 and then connected to the decoder 311 through the deep-trenched contact holes 310. The same deep-trenched contact holes are required for connecting the metal bit lines 307 on top of the 3D array to the bit line decoder on the silicon surface as well.

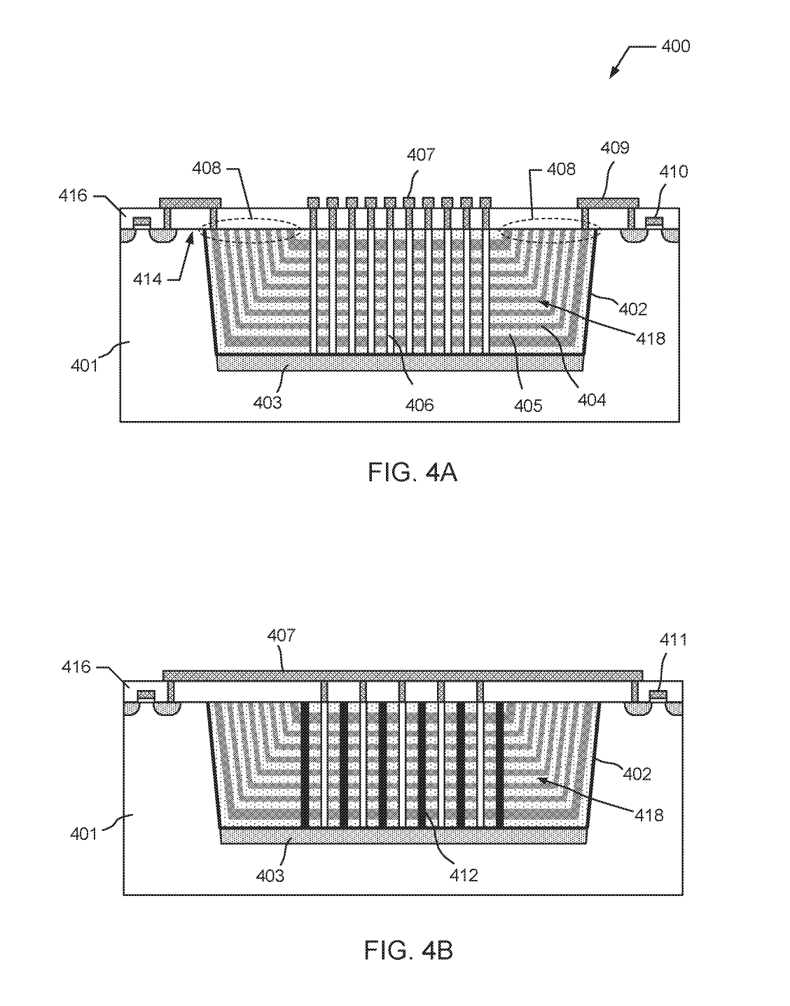

FIG. 4A shows an exemplary embodiment of a 3D NAND SONOS flash array 400 constructed using an exemplary embodiment of the novel 3D array architecture and process. The array 400 includes a silicon substrate 401, trench area (shown generally at 418) defined by trench wall 402 for the 3D array, diffusion 403 for the source line and multiple word line layers 404. Also included are insulator layers 405 between word line layers and channels 406 for the NAND string cells. The channels 406 are formed by trenching holes through all the word line layers and filling with polysilicon. Metal bit lines 407 are also included. It should be noted that by forming the 3D array inside the trench area 418, at the edge of the trench the deposited multiple word line layers 404 will follow the contour of the trench wall 402 and will be automatically turned toward vertical and brought up to the silicon surface 414 as shown at the regions 408. The region 416 is an insulator such as an oxide region that covers the array.

The word line layers above the silicon surface 414 can be removed by chemical-mechanical planarization (CMP) or any suitable etching process. This exposes the ends of all the word line layers for metal connection (see region 408). Because all the word lines and bit lines are at the same level as the silicon surface, they may be connected to the decoders by using a standard back-end process, such as shown by the metal line 409 that connects to the word line decoder 410.

FIG. 4B shows a cross-section view 418 taken along the direction of bit line 407 in the array 400. For example, the metal bit line 407 is connected to the bit line decoder 411 by standard back-end metal line connection process. Word line ‘slits’ 412 that define the word line pattern may be filled with an insulator such as oxide or a conductor such as metal to connect to the bottom source line diffusion.

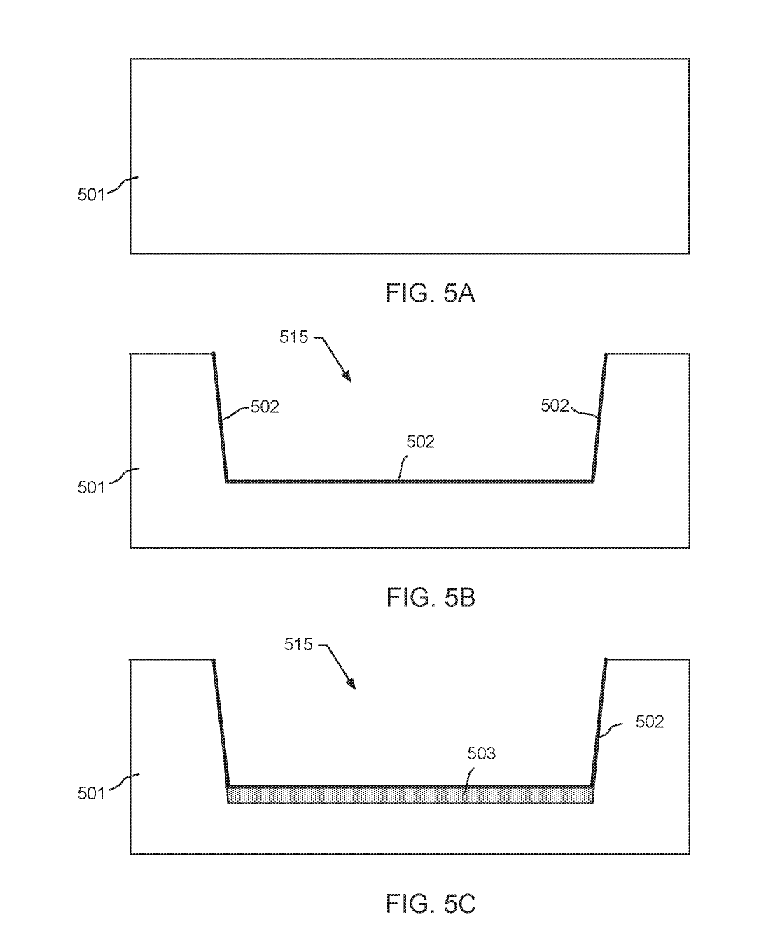

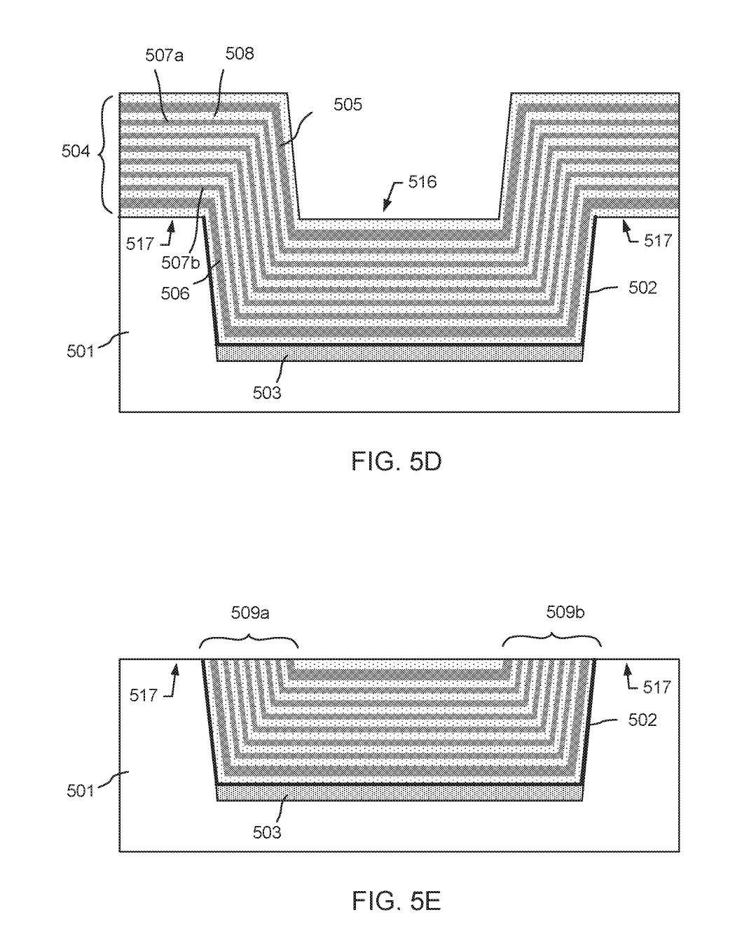

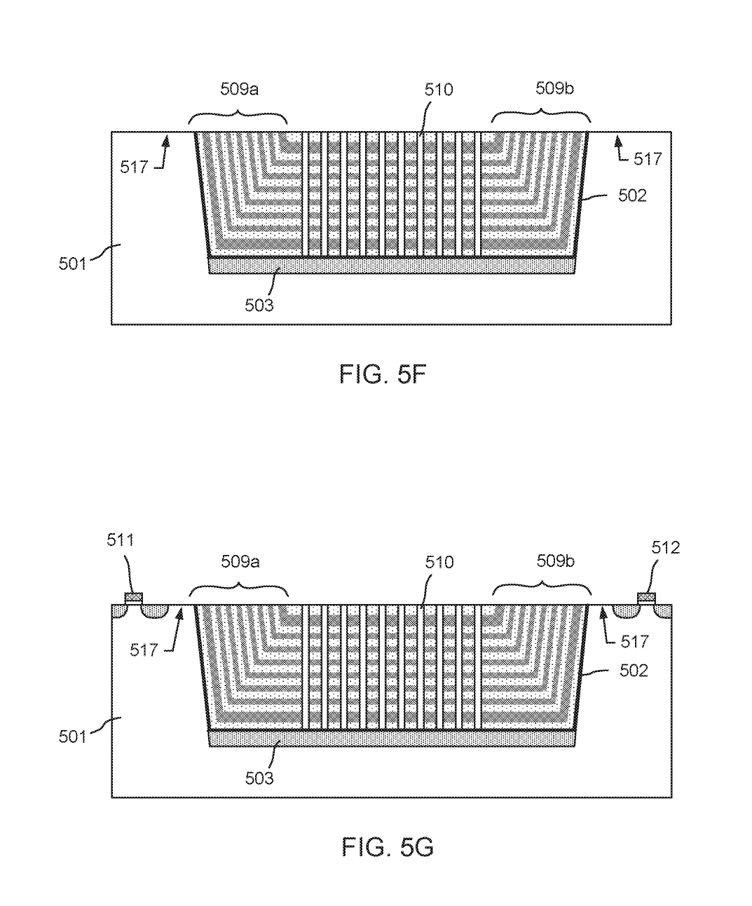

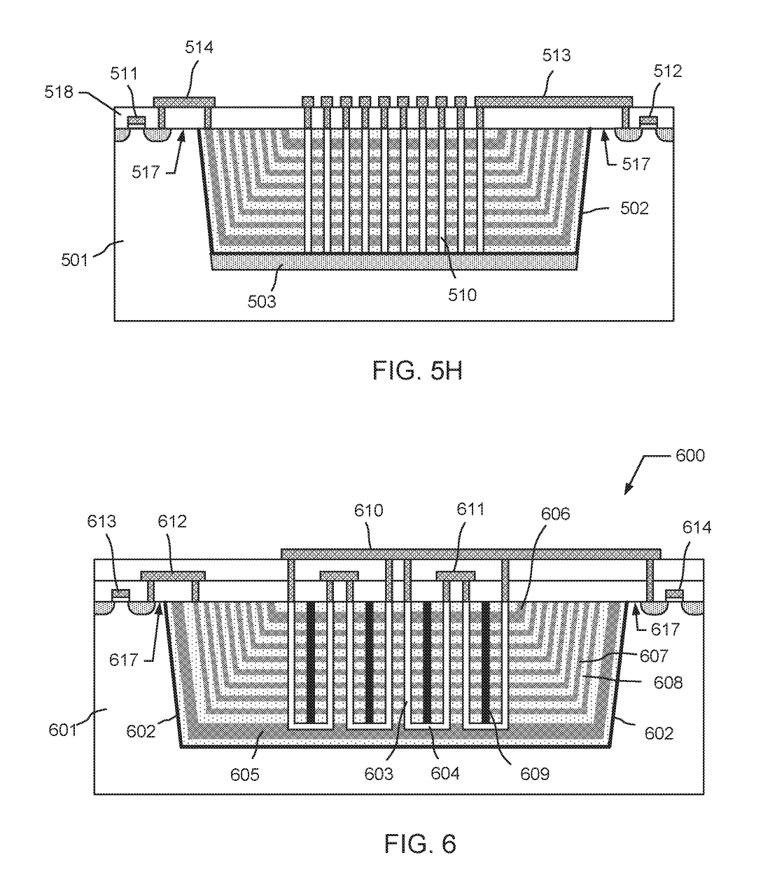

FIGS. 5A-H show exemplary embodiments of a simplified process flow for constructing a novel 3D array inside a substrate trench according to the invention. For this description, a 3D NAND array using SONOS flash memory cells are used as an example. However, the process flow may be modified according to the type of cells, array architectures, technologies, and processes. A person skilled in the art would recognize that these variations are within the scope of the invention.

FIG. 5A shows an exemplary substrate material 501, such as silicon, to be used for a 3D NAND flash array. Any other material may be used, such as oxide for a SOI process. FIG. 5B shows an exemplary embodiment of a trench 515 (also referred to as a “substrate trench”) that is an open region formed in the substrate 501 and that is defined by wall 502 (also referred to as “trench wall”). The dimensions of the trench 515 are discussed in greater detailed below. The trench 515 forms generally a rectangular space but in other embodiment, the trench 515 can form any desired three-dimensional space, such as a square space, circular space, oval space, triangular space, or any other space or region. Thus, the trench space is defined by the trench wall 502. FIG. 5C shows an exemplary embodiment of a diffusion region 503 that forms a source line for the 3D NAND flash array.

FIG. 5D shows an exemplary embodiment of multiple alternate layers of conductors and insulators that are deposited in the trench to form stacked word line layers 504. For example, the conductor layers (e.g., 505, 507a, etc.) are polysilicon or metal layers. In an exemplary embodiment, the insulating layers between the conductor layers, such as layer 508, are oxide. In an exemplary embodiment, the top conductor layer 505 may be a thicker layer to form drain select gates (DSG) and the bottom conductor layer 506 also may be a thicker layer to form source select gates (SSG). The remaining conductor layers can be thinner layers to form word lines, such as word lines 507a to 507b. As illustrated in FIG. 5D, the word line layers are deposited in the trench and flow upward (e.g., vertically) to follow the contour of the trench wall. It should be noted that it is desirable to form the stacked word line layers so that the height of the stacked word line layers 504 is the same or substantially the same as the depth of the trench. As a result, the top of the stacked word line layers (indicated at 516) inside the trench is close to the level of the top surface of the silicon substrate (indicated at 517). However, it should also be noted that there is no limit for the trench depth, such that any trench depth may be used as permitted by the back-end processes to form the device.

FIG. 5E show an exemplary embodiment of the 3D NAND flash array with the excess word line layers removed. For example, in an exemplary embodiment, the stacked word line layers 504 above the top surface 517 of the silicon substrate 501 are removed by a planarization process, such as CMP or any suitable etching process. This will expose the ends of the word line layers near the walls 502 of the trench, (as indicated at 509a and 509b) for metal connections. At this point, word line slits can be etched to form word line patterns.

FIG. 5F shows an exemplary embodiment of the 3D NAND flash array with etched word lines. For example, cell strings are formed by a pattern-trench process to etch holes 510 (or openings) through all the word line layers. The holes 510 are filled with gate dielectric layers, charge-trapping layers, and then polysilicon to form the channels of the cell strings.

FIG. 5G shows an exemplary embodiment of the 3D NAND flash array with periphery circuits added. For example, after the 3D array is formed inside the trench, the appropriate processes can be used to form the logic and periphery circuits such as decoders 511 and 512 on the silicon surface 517.

FIG. 5H shows an exemplary embodiment of the 3D NAND flash array with word lines and bit lines add. For example, an appropriate back-end process can be used to connect word lines 514 and bit lines 513 to the decoders 511 and 512, respectively. The region 518 is an insulator, such as an oxide region that covers the array.

FIG. 6 shows an exemplary embodiment of a 3D NAND flash array 600 with ‘U’ shaped folded channels constructed in accordance with a novel 3D process and architecture of the present invention. For example, the array 600 includes a silicon substrate 601 and the array is formed inside a trench in the silicon substrate 601. The trench is an opening or space in the silicon substrate 601 defined by trench walls 602. The array 600 includes ‘U’ shape strings having channels (e.g., 603) with bottom parts (e.g., 604) of the strings that are buried inside a back-gate 605. The array uses multiple word line layers (e.g., 607) and insulator layers (e.g., 608) between word line layers with a thicker word line layer 606 for select gates. Word line slits or “openings” (e.g., 609) define the word line patterns. The array 600 also includes metal bit lines 610 and metal source lines 611. It should be noted that in accordance with the novel architecture, a connection region to connect to all the word lines, bit lines, and source lines is located on the same level or substantially same level as the surface 617 of the silicon substrate 601. Therefore, these lines can be connected to periphery circuits by using standard back-end processes. For example, metal line 612 connects a word line to the word line decoder 613 and metal line 610 connects a bit line to the bit line decoder 614.

It should also be noted that in the various exemplary embodiments, the number of the trenches that are used is not limited. Therefore, the substrate may contain multiple trenches for multiple 3D arrays. Moreover, the trenches may have different depths and/or other characteristics depending on the requirement of the array architecture.

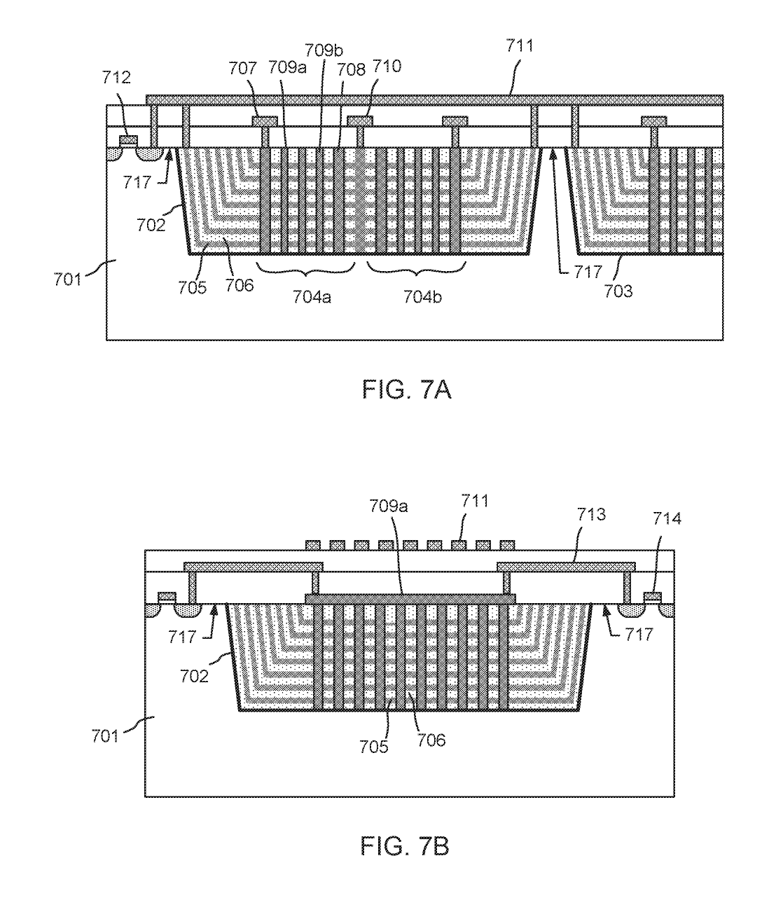

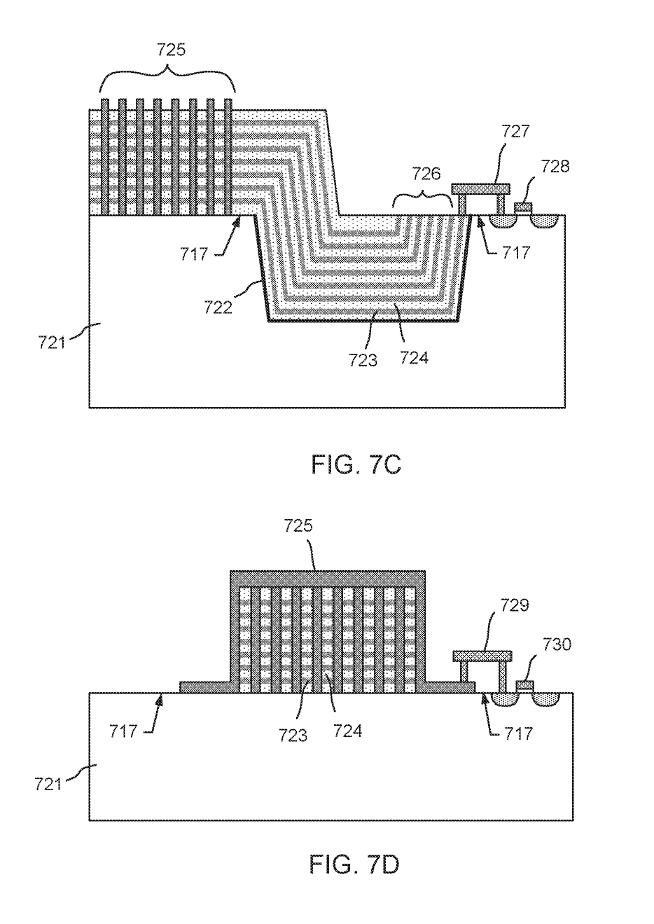

FIGS. 7A-B show exemplary embodiments of another implementation of the novel 3D process and architecture using a 3D NAND flash array having horizontal channels and a corresponding cross-sectional view.

FIG. 7A show an exemplary embodiment of another implementation of the novel 3D architecture in which a 3D NAND flash array is formed having horizontal channels (bit lines). The silicon substrate 701 contains multiple trench areas defined by trench walls 702 and 703. Each trench contains multiple cell strings. For example, the trench defined by wall 702 contains cell strings 704a and 704b. Also shown are horizontal channels (e.g., 705) and insulator layers (e.g., 706) between channels. A horizontal drain select gate (DGS) layer 707 and a horizontal source select gate (SSG) layer 708 are also shown. Furthermore, word line layers (e.g., 709a, 709b) and source line layer 710 are shown. Thus, as shown in FIG. 7A, the bit lines of each trench area are deposited to follow the contour of the trench wall and are brought up to the same or substantially same level as the silicon substrate surface 717. This allows for easy access to connect to the bit lines. For example, the bit line 705 is connected by metal bit line 711 to the bit line decoder 712. This may be done by using standard back-end processes that eliminates the complicated back-end processes of the traditional 3D arrays.

FIG. 7B shows an exemplary cross-sectional view of the array of FIG. 7A taken along a word line. For example, this view illustrates how the word line layer 709a can be connected to the word line decoder 714 by the metal layer 713.

In various exemplary embodiments, the novel architecture is not limited to configurations where the entire 3D array is located inside the trench. For example, in other embodiments, there may be only a part of the 3D array, or only some part of the array's connections located inside the trench as illustrated below.

FIGS. 7C-D show exemplary embodiments of another implementation of the novel 3D process and architecture in which only a 3D array's word line connection portion is located inside a trench and a corresponding cross-sectional view

FIG. 7C shows an exemplary embodiment of another implementation of the novel 3D architecture in which only a 3D array's word line connection portion is located inside a trench. FIG. 7C shows a silicon substrate 721 and a trench formed by trench wall 722 that surrounds the array or one side of the array. Word lines layers 723, insulator layers 724 between the word line layers, and bit lines 725 are also shown. In should be noted that in another embodiment, the position of the bit lines and the word lines are swapped. The word line layers in the trench area are deposited to follow the contour of the trench wall 722 and form the topology as shown. A portion of the word line layers (shown at 726) is removed by a suitable etching process so that contact regions of the word lines are substantially level with the top surface 717 of the silicon substrate. This allows the word lines be connected to the word line decoders 728 through the metal layer (e.g., 727) by using standard back-end processes. However, word lines above the surface of the silicon substrate (e.g., in the region of bit lines 725) utilize a more complex connection process as discussed below.

FIG. 7D shows an exemplary cross-sectional view of the array shown in FIG. 7C taken along the bit line direction. In an exemplary embodiment, the bit lines 725 are brought down to the surface 717 of the silicon substrate and therefore they can be connected to the bit line decoder 730 through metal layer 729 by using standard back-end processes as well.

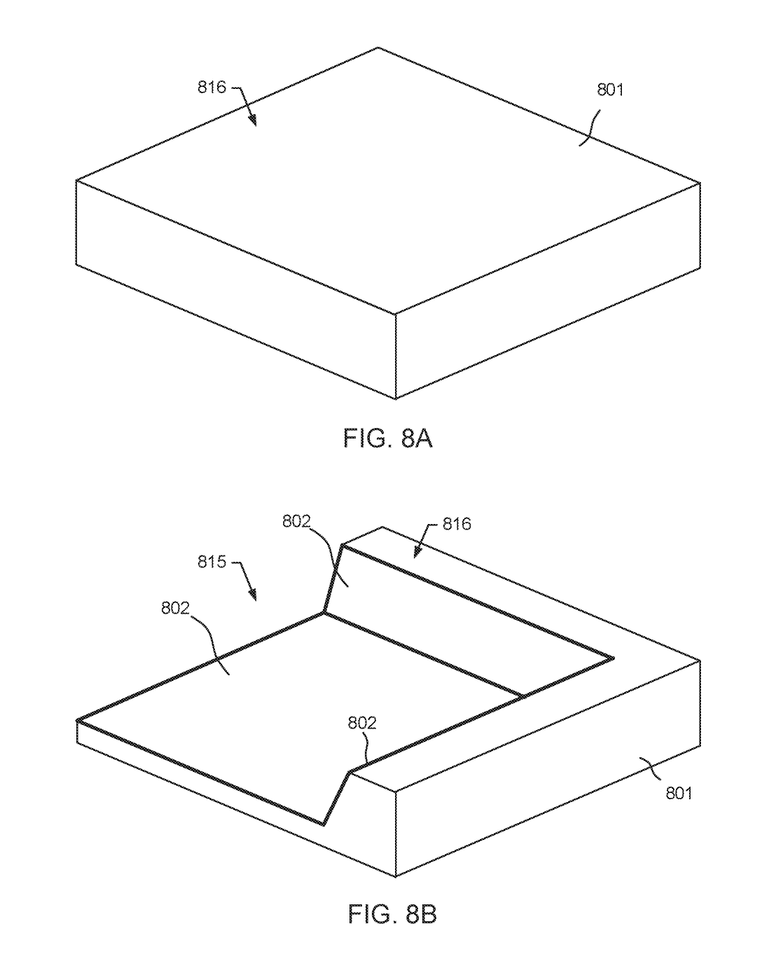

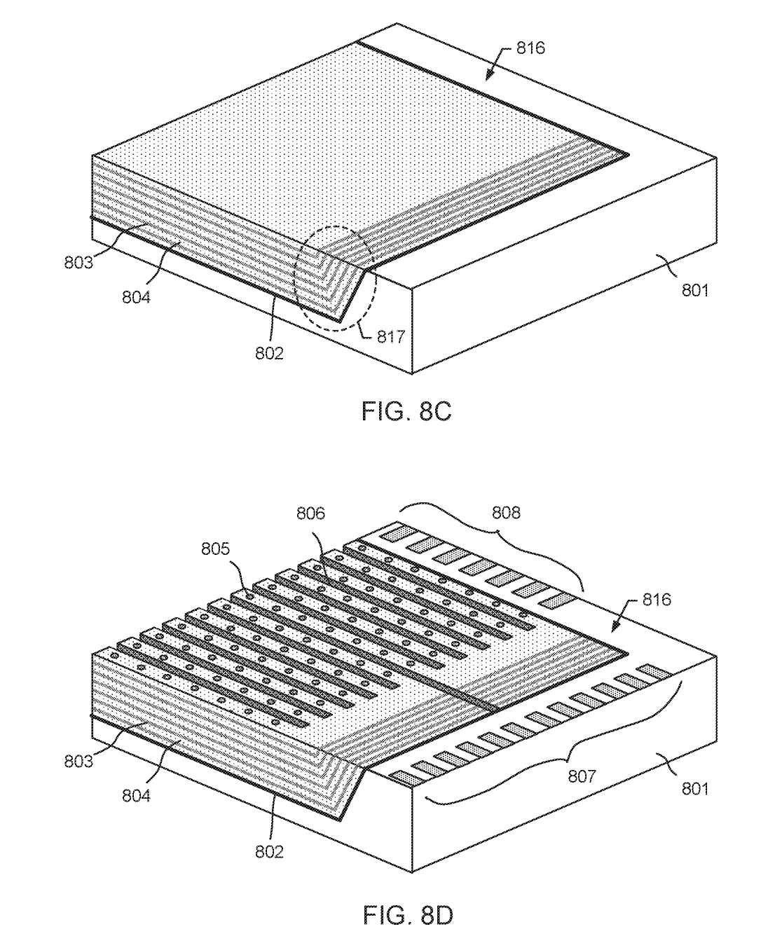

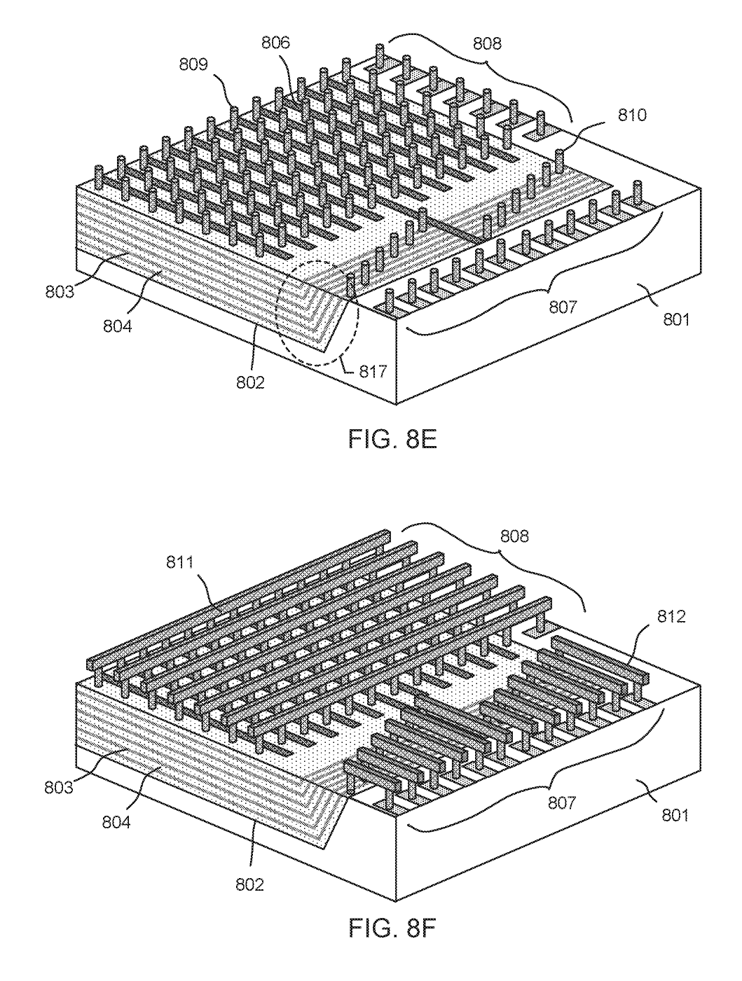

FIGS. 8A-F show exemplary embodiments of an implementation of the novel 3D architecture and process in which simplified process steps according to the invention are shown and described.

FIG. 8A shows an exemplary embodiment of a substrate 801 that may be silicon or an insulator depending on the process used. The substrate 801 has a top surface 816. FIG. 8B shows an exemplary embodiment of a trench area (shown generally at 815) defined by trench walls 802 that are formed in the substrate 801. FIG. 8C shows an exemplary embodiment illustrating how the trench 815 is filled by depositing multiple word line layers 803 and insulator layers 804. In an exemplary embodiment, the word line and insulator layers are deposited to follow along the contour of the trench wall 802 so that the horizontal layers turn substantially vertical as illustrates at 817. The word line and insulator layers that extend above the surface 816 of the silicon substrate 801 are removed by a planarization process so that the ends are at the same or substantial the same level as the surface 816.

FIG. 8D shows an exemplary embodiment illustrating how word line slits 806 are formed to define the word line patterns. The cell channels 805 are trenched and filled with suitable materials. After the 3D array's front-end process is complete, the standard front-end process may take place to form the logic and periphery circuits, such as the active regions for word line decoder 807 and bit line decoder 808.

FIG. 8E shows an exemplary embodiment illustrating how a standard back-end process can be used to form the bit line contacts 809, word line contacts 810, and contacts for the word line decoder 807 and the bit line decoder 808. For example, contacts can be connected to an end (or edge) of each word line in the connection region 817 where the word lines turn vertical following the contour of the trench. FIG. 8F shows an exemplary embodiment illustrating how metal bit lines 811 and metal word lines 812 are formed to connect to the bit lines and word lines to the decoders by using the standard back-end process.

According to the invention, the connection of the word line or bit line layers at the edge of a trench may be formed by any suitable process. In the case of extra thin word line and insulator layers, special processes may be used to prevent contacts shorting to unwanted layers.

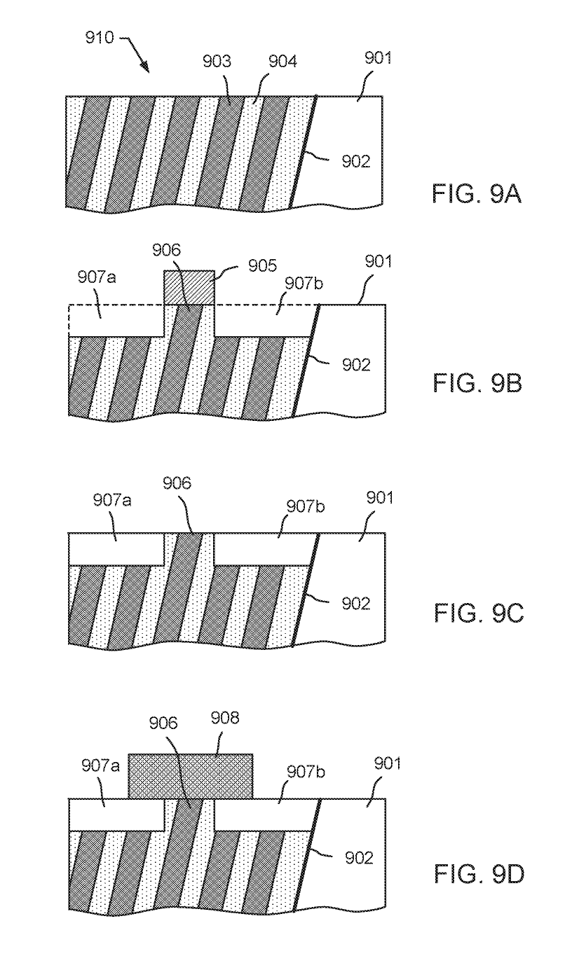

FIGS. 9A-D show exemplary embodiments of a process to prevent shorting of word line or bit line layers at the edge of a trench according to the invention.

FIG. 9A shows an exemplary embodiment of a substrate 901 comprising a trench (shown generally at 910) defined by trench wall 902. Also shown are word line or bit line layers (e.g., 903) and insulator layers (e.g., 904) deposited within the trench 910 and following the contour of the trench wall 902. FIG. 9B shows an exemplary embodiment of a photoresist or hard mask 905 that covers a wanted or desired word line or bit line layer 906. A pattern-etch is applied to reduce the height of unwanted area or regions as indicated at 907a and 907b. FIG. 9C shows an exemplary embodiment illustrating how the unwanted area or regions 907a and 907b are filled with insulator such as oxide and the hard mask 905 is removed to expose the word line or bit line layer 906. This process allows more misalignment margin for the following contact hole etching. This process also allows larger contacts to be used. FIG. 9D shows an exemplary embodiment illustrating how a conductor pad such as metal 908 can be formed on the wanted or desired word line or bit line layer 906 to further increase the process margin.

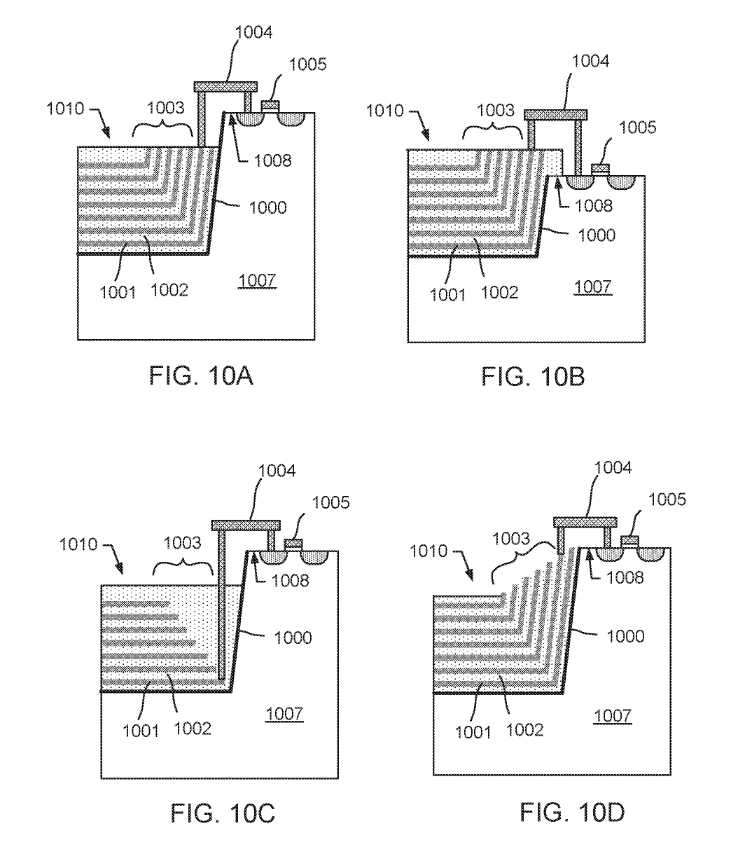

FIGS. 10A-D show exemplary embodiments of additional examples for forming connections for multiple word line or bit line layers in accordance with the invention.

FIG. 10A shows an exemplary embodiment of a substrate 1007 comprising a trench (shown generally at 1010) having trench wall 1000. Also shown are word line or bit line layers (e.g., 1001) and insulator layers (e.g., 1002) deposited within the trench 1010 and following the contour of the trench wall 1000. It should be noted that in this embodiment, the connection region 1003 to the word line or bit line layers is at a level that is lower than the level of the silicon surface 1008. As a result, the word line or bit line is connected to a decoder 1005 through a metal layer, such as metal layer 1004 that connects to the end of the word line or bit line in the connection region 1003.

FIG. 10B shows an exemplary embodiment of a substrate 1007 comprising a trench (shown generally at 1010) having trench wall 1000. Also shown are word line or bit line layers (e.g., 1001) and insulator layers (e.g., 1002) deposited within the trench 1010 and following the contour of the trench wall 1000. In this embodiment, the connection region 1003 of the word line or bit line layers is at a level that is higher than the level of the silicon surface 1008. The word line or bit line is connected to a decoder 1005 through metal layer 1004 that connects to the end of the word line or bit line in the connection region 1003.

FIG. 10C shows an exemplary embodiment of a substrate 1007 comprising a trench (shown generally at 1010) having trench wall 1000. Also shown are word line or bit line layers (e.g., 1001) and insulator layers (e.g., 1002) deposited within the trench 1010. In this embodiment, the connection region 1003 to the word line or bit line layers has a first type of staircase topology where the word lines or bit lines are at a level that is below the level of the silicon surface 1008. The word line or bit line is connected to a decoder 1005 through metal layer 1004.

FIG. 10D shows an exemplary embodiment of a substrate 1007 comprising a trench (shown generally at 1010) having trench wall 1000. Also shown are word line or bit line layers (e.g., 1001) and insulator layers (e.g., 1002) deposited within the trench 1010 and following the contour of the trench wall 1000. In this embodiment, the connection region 1003 to the word line or bit line layers has a second type of staircase topology where the ends of the word lines or bit lines ramp up to the level of the silicon surface 1008. The word line or bit line is connected to a decoder 1005 through metal layer 1004. It should be noted that the variations shown in FIGS. 10A-D may be implemented by different process flows, however, a person skilled in the art will recognize that these variations are within the scope of the invention.

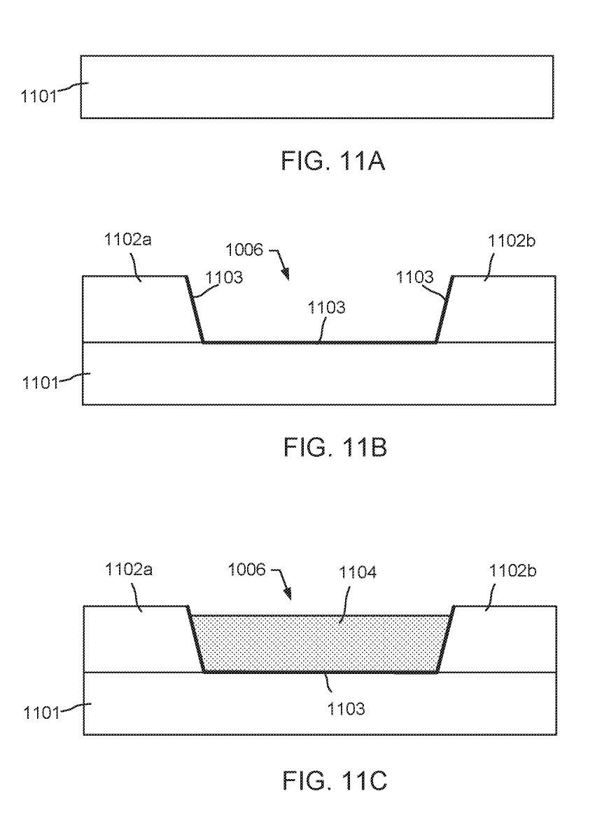

FIGS. 11A-C show various exemplary embodiments where a trench for a 3D array is formed using another suitable process, for example, by using epitaxial layers.

FIG. 11A shows an exemplary embodiment of a substrate 1101 that may be silicon or an insulator layer. FIG. 11B shows an exemplary embodiment of epitaxial silicon layers 1102a and 1102b that are grown on top of the substrate 1101 to form a trench area 1006 defined by trench walls 1103. FIG. 11C shows an exemplary embodiment of a 3D array 1104 formed inside the trench area 1106. In an exemplary embodiment, the logic and periphery circuits may be formed on the epitaxial layers 1102a and 1102b.

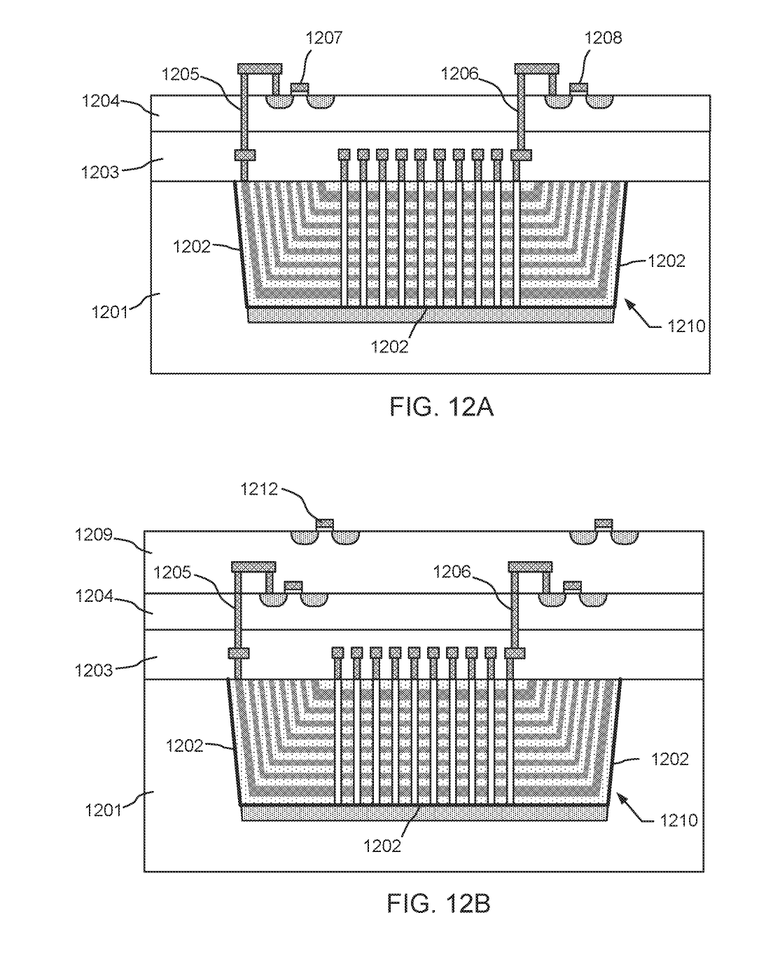

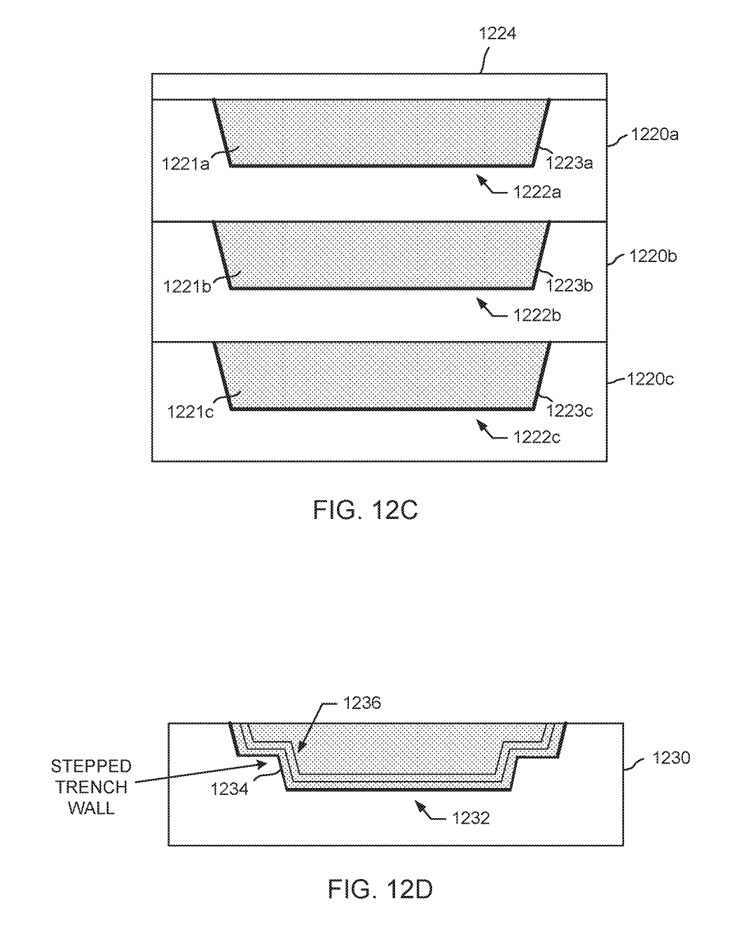

FIGS. 12A-B show additional exemplary embodiments for forming connections for multiple word line or bit line layers in accordance with the invention.

FIG. 12A shows an exemplary embodiment of a substrate 1201 comprising a trench (shown generally at 1210) having trench wall 1202. As described above, a 3D array is formed within the trench 1210 and includes layers that are deposited to follow the contour of the trench wall 1202. Also shown are an insulation layer 1203 and a silicon layer 1204 that may be formed by any suitable process, such as for example, epitaxial growth.

The logic and periphery circuits are formed in top of the silicon layer 1204. For example, the word lines and bit lines of the 3D array are connected to the decoders 1207 and 1208 on top of the silicon layer 1204 through contacts 1205 and 1206. Because the connections of the 3D array according to the invention are located on top of the array, it is very suitable for the “memory-below-logic” structure.

FIG. 12B shows another exemplary embodiment where more than one layer of silicon is added on top of the 3D array. For example, in this embodiment, there are two silicon layers 1204 and 1209 formed or bonded on top of the 3D array. Thus, allowing for more decoders (e.g., decoder 1212) to be mounted and connected to the array.

It should also be noted that one or more substrate layers can be added that each contain a 3D array in accordance with the invention and that these arrays can be bonded together to increase the memory density.

FIG. 12C shows another exemplary embodiment comprising stacked multiple layers of silicon substrates having 3D arrays formed in corresponding trenches in accordance with the invention. For example, in this embodiment, three substrate layers 1220a, 1220b, and 1220c are stacked on top of each other. The three substrate layers have three trench regions 1222a, 1222b, 1222c formed by three trench walls 1223a, 1223b, 1223c, respectively. The three trench regions contain 3D arrays 1221a, 1221b, and 1221c that are deposited within their respective trench regions to follow the contour of the trench walls in accordance with the invention. The word lines and bit lines of each 3D array can be connected to decoders located on each substrate. In another embodiment, the word lines and bit lines of each 3D array can be connected to decoders located on one substrate such as substrate 1220a, for example. In another embodiment, the word lines and bit lines of each 3D array can be connected to another substrate 1224 that contains logic and periphery circuits. The substrate 1224 may be formed or bonded on top or bottom of the stacked 3D array layers. In accordance with the invention, there is virtually no limit for the number of logic layers and memory layers that may be stacked.

FIG. 12D shows an exemplary embodiment of a stepped wall trench formed in a substrate in accordance with the invention. As illustrated in FIG. 12D, a silicon substrate 1230 includes trench 1232 defined by trench wall 1234. In an exemplary embodiment, the trench wall 1234 is stepped such that the layers 1236 deposited within the trench experience shorter vertical runs. Thus, instead of having deposited layers that have one vertical incline that extends to the top of the silicon substrate, the stepped trench wall results in multiple shorter vertical inclines for the deposited layers.

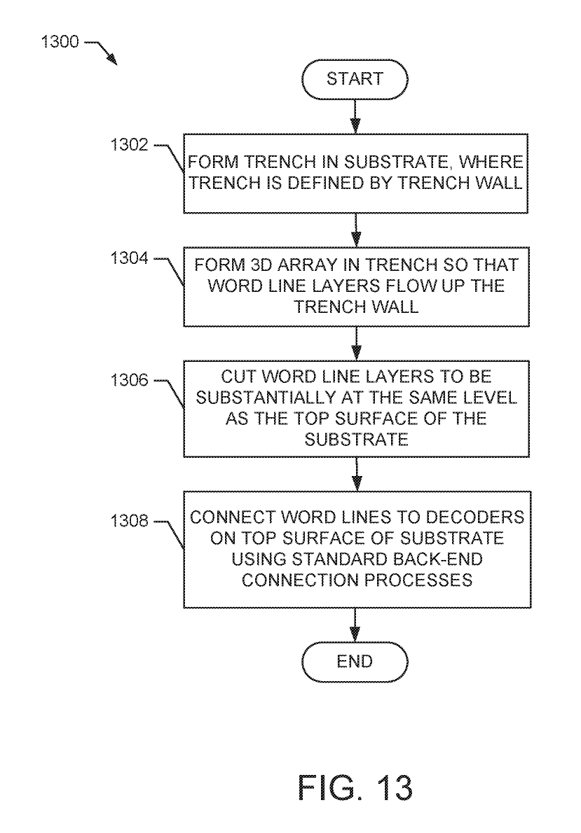

FIG. 13 shows an exemplary embodiment of method 1300 for performing process operations to implement a novel architecture to form a 3D array inside a trench of a substrate. For example, the method is suitable for use to form the 3D array device shown in FIGS. 5A-H.

At block 1302, a trench is formed in a substrate where the trench is defined by a trench wall. For example, as illustrated in FIG. 5B, a trench (shown generally at 515) is formed in the substrate 501. The trench 515 is defined by trench walls 502. In an alternative embodiment, the trench can be formed using epitaxial layers as described above.

At block 1304, a 3D array is formed in the trench. For example, as illustrated in FIGS. 5C-D a 3D array 516 is formed (or deposited) in the trench 515 so that word lines (or alternatively, bit lines layers) are deposited to follow the contour of the trench wall 502. For example, the stack layers 504 of bit lines or word lines flow up the trench wall 502 and over a top surface 517 of the substrate 501.

At block 1306, the word line or bit line layers are cut to have ends that are substantially at the same level as the top surface of the substrate. For example, as illustrated in FIGS. 5D-E the stack word line or bit line layers 504 are cut to have ends that are substantially at the same level as the top surface 517 of the substrate 501. In an exemplary embodiment, the stack word line or bit line layers 504 are cut or removed using a planarization process, such as CMP or any suitable etching process resulting in the connection regions 509 where the ends of the layers are exposed for connection.

At block 1308, the cut word lines or bit lines are connected to decoders on or above the top surface of substrate using standard back-end processes. For example, as illustrated in FIG. 5G-H, decoders 511 and 512 are mounted on the top surface 517 of the substrate 501 and the word lines or bit lines are connected to the decoders using metal lines 513 and 514 in a standard back-end process.

Thus, the method 1300 operates to implement a novel architecture to form a 3D array inside a trench of a substrate. It should be noted that the method 1300 is exemplary and that the disclosed operations may be combined, rearranged, added to, deleted, and/or modified within the scope of the embodiments.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. An apparatus, comprising:
a substrate
a trench region in the substrate that is defined by a trench wall; and
a 3D array having stacked word line layers formed in the trench region that follow a contour of the trench wall.

2. The apparatus of claim 1, wherein the substrate has a top surface, wherein the stacked word line layers form a connection region that is substantially at the same level as the top surface, and wherein ends of the stacked word line layers are exposed in the connection region.

3. The apparatus of claim 2, wherein the stacked word line layers follow the contour to form substantially vertical layers in the connection region.

4. The apparatus of claim 2, further comprising metal lines connecting the ends to periphery circuitry.

5. The apparatus of claim 1, wherein the trench region has a depth that is substantially equal to the height of the 3D array.

6. The apparatus of claim 1, wherein the stacked word line layers comprise alternating conductive and insulating layers.

7. The apparatus of claim 1, wherein the stacked word line layers form stacked bit line layers.

8. The apparatus of claim 1, wherein the trench is formed by etching the substrate.

9. The apparatus of claim 1, wherein the trench is formed by stacking epitaxial layers on the substrate.

10. A method comprising:
forming a trench region in a substrate that has a top surface, wherein the trench region is defined by a trench wall; and
forming a 3D array having stacked word line layers in the trench region so that the stacked word line layers follow a contour of the trench wall and have exposed ends substantially at a level of the top surface.

11. The method of claim 10, further comprising removing a portion of the stacked word lines above the top surface to form a connection region that is substantially at the level as the top surface.

12. The method of claim 10, further comprising connecting the ends of the stacked word lines to decoders mounted on the top surface of the substrate using metal lines.

13. The method of claim 10, wherein forming the trench region comprises forming the trench region to have a depth that is substantially equal to a height of the 3D array.

14. The method of claim 10, wherein forming the 3D array comprises depositing the stacked word line layers using alternating conductive and insulating layers.

15. The method of claim 10, further comprising configuring the stacked word line layers to form stacked bit line layers.

16. The method of claim 10, wherein forming a trench region comprises forming the trench region by etching the substrate.

17. The method of claim 10, wherein forming a trench region comprises forming the trench region by stacking epitaxial layers on the substrate.

18. A 3D array formed by performing the operations of:
forming a trench region in a substrate that has a top surface, wherein the trench region is defined by a trench wall; and
forming a 3D array having stacked word line layers in the trench region so that the stacked word line layers follow a contour of the trench wall and have exposed ends substantially at a level of the top surface.

19. The 3D array of claim 18, further formed by performing an operation of connecting the ends of the stacked word lines to decoders mounted on the top surface of the substrate using metal lines.

20. The 3D array of claim 18, further formed by performing an operation of forming the trench region to have a depth that is substantially equal to a height of the 3D array.
